(19) United States
(12) Patent Application Publication
(10) Pub. No.: US 2013/0309865 A1
(43) Pub. Date: Nov. 21, 2013

(54) METHOD OF MANUFACTURING SUBSTRATE FOR MOUNTING ELECTRONIC DEVICE

(71) Applicant: SAMSUNG ELECTRONICS CO., LTD., Suwon-si (KR)

(72) Inventors: Shi Young LEE, Seoul (KR); Tae Hyung KIM, Gyeonggi-do (KR); Gi Bum KIM, Gyeonggi-do (KR); Yu Seung KIM, Seoul (KR); Ju Hyun KIM, Gyeonggi-do (KR); Jin Gi HONG, Gyeonggi-do (KR)

(21) Appl. No.: 13/894,170

(22) Filed: May 14, 2013

(30) Foreign Application Priority Data
May 16, 2012 (KR) 10-2012-0052119

(51) Int. Cl. H01L 21/768

(52) U.S. Cl. CPC H01L 21/76802
USPC 438/667

(57) ABSTRACT

There is provided a method of manufacturing a substrate for mounting an electronic device. The method includes disposing a protective layer on a surface of the substrate except for an edge portion thereof . An oxide film is disposed on the entirety of the surface of the substrate except for where the protective layer is disposed The oxide film is grown. A through hole is formed in a thickness direction of the substrate by selectively etching the protective layer. The oxide film is removed. In the manufacturing method, defects in the substrate for mounting an electronic device may be reduced and manufacturing costs can be reduced.

### CROSS-REFERENCE TO RELATED APPLICATION

This application claims priority to Korean Patent Application No. 10-2012-0052119, filed on May 16, 2012, in the Korean Intellectual Property Office, the disclosure of which is incorporated herein by reference.

### TECHNICAL FIELD

The present application relates to a method of manufacturing a substrate for mounting an electronic device.

### BACKGROUND

A light emitting diode (LED) is a device including a material able to emit light, in which energy generated through electron-hole recombination in semiconductor junction parts is converted into light to be emitted therefrom. LEDs are commonly employed as light sources in general illumination devices, display devices, and the like, and the development of LEDs has thus been accelerated.

In particular, recently, the development and employment of gallium. nitride-based LEDs has increased, and mobile device keypads, vehicle turn signal lamps, camera flashes, and the like, using such a gallium nitride-based LED, have been commercialized, and in line with this, the development of general illumination devices using LEDs has accelerated. Like the products to which they are applied, such as a backlight unit of a large TV, a vehicle headlamp, a general illumination device, and the like, the current trend is for LEDs to be increasingly used in large-sized products having high outputs and high efficiency. Thus, the characteristics of LEDs used in such products are required to satisfy the characteristics required of the LEDs at a high level.

With current LED technology, a light emitting element is mounted on a substrate for mounting an electronic device in order to achieve a highly integrated LED. In this case, the manufacturing process of the substrate for mounting an electronic device is relatively complicated, leading to extended manufacturing times and excessive manufacturing costs.

### SUMMARY

An aspect of the present application provides a method of manufacturing a substrate for mounting an electronic device in which the manufacturing time and costs are reduced.

According to an aspect of the present application, there is provided a method of manufacturing a substrate for mounting an electronic device. The method includes forming a protective layer on a surface of the substrate, except for an edge portion thereof. An oxide film is disposed on the entirety of the surface of the substrate, except for the protective layer. The oxide film is grown. A through hole is formed in a thickness direction of the substrate by selectively etching the protective layer The oxide film is removed.

The substrate may be a Si substrate.

The edge portion may have a width of 30 μm in a direction from an edge of the substrate toward a center thereof.

The protective layer may be formed by depositing a nitride film on the substrate.

The nitride film may be selected from the group consisting of SiON, SiNₓ and a mixture thereof.

The oxide film may be deposited by supplying O₂ gas to the substrate.

The oxide film may be grown to have a thickness of 5 μm or greater.

The step of forming the through hole may include forming a mask having patterns on the protective layer. Selective etching of the protective layer exposed between the patterns allows a portion of the substrate to be exposed. The exposed portion of the substrate is etched to form the through hole.

The step of selective etching of the protective layer may be performed using a CHₓF_{y} gas.

The CHₓF_{y} gas may be a CH₂F₂ gas or CH₃F gas.

The protective layer and the oxide film may have different etching rates.

The method may further include the step of forming an electrode by filling the through hole with metal. In another example, a method of manufacturing a substrate is provided. The method includes disposing a protective layer on a first surface of the substrate. An oxide seed layer is disposed on a second surface of the substrate. The first and second surfaces do not overlap and the oxide seed layer is disposed over one or more edges of the substrate. The oxide seed layer is grown to form an oxide film. The oxide film has a thickness greater than the oxide seed layer. A plurality of through holes are formed in a thickness direction of the substrate by selectively etching the protective layer. The oxide film is removed.

Additional advantages and novel features will be set forth in part in the description which follows, and in part will become apparent to those skilled in the art upon examination of the following and the accompanying drawings or may be learned by production or operation of the examples. The advantages of the present teachings may be realized and attained by practice or use of various aspects of the methodologies, instrumentalities and combinations set forth in the detailed examples discussed below.

### BRIEF DESCRIPTION OF THE DRAWINGS

The above and other aspects, features and other advantages of the present application will be more clearly understood from the following detailed description taken in conjunction with the accompanying drawings, in which:

FIG. 1 is a plan view of a substrate according to an example of the present application; and

FIGS. 2 through 9 are schematic cross-sectional views illustrating a method of manufacturing a substrate for mounting an electronic device according to an example of the present application.

### DETAILED DESCRIPTION

In the following detailed description, numerous specific details are set forth by way of examples in order to provide a thorough understanding of the relevant teachings. However, it should be apparent to those skilled in the art that the present teachings may be practiced without such details.

The application may, however, be exemplified in many different forms and should not be construed as being limited to the specific examples set forth herein. Rather, these examples are provided so that this disclosure will be thorough and complete, and will fully convey the scope of the application to those skilled in the art. In the drawings, the shapes and dimensions of elements may be exaggerated for clarity, and the same reference numerals will be used throughout to designate the same or like elements.

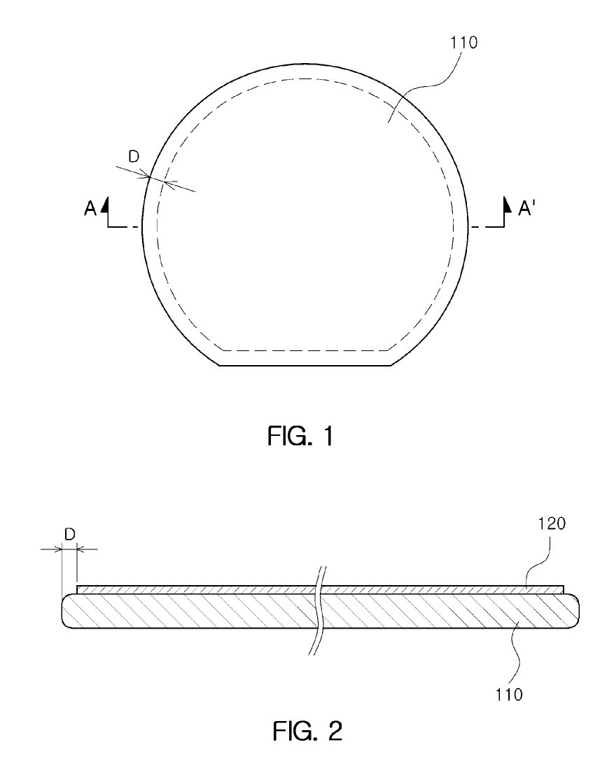

FIG. 1 is a plan view of a substrate according to an example, and FIGS. 2 through 9 are schematic cross-sectional views illustrating a method of manufacturing a substrate for mounting an electronic device according to an example of the present application.

As shown in FIG. 2, a protective layer 120 maybe formed on a substrate 110.

The substrate 110 maybe a plate-shaped substrate. The substrate 110 may be formed of Si, sapphire, ZnO, GaAs, SiC, MgAl₂O₄, MgO, LiAlO₂, LiGaO₂, GaN or the like. In the present example, a Si substrate, in particular, a Si wafer having a diameter of eight inches and a thickness of 400 μm, maybe used as the substrate 110.

As shown in FIG. 1, an edge portion D may be formed along an edge of the substrate 110. The edge portion D may be a region of the substrate on which a separate device or circuit pattern is not provided, generally known as a bevel region. In this example, the edge portion D may be defined as a region having a width of 30 μm in a direction from the edge of the substrate 110 toward the center thereof.

Since the edge portion D is disposed around the edge of the substrate 110 and is thinner than the other portion of the substrate, it may be easily etched and damaged during the manufacturing process. Defects in the edge portion D can lead to damage of the entire substrate 110.

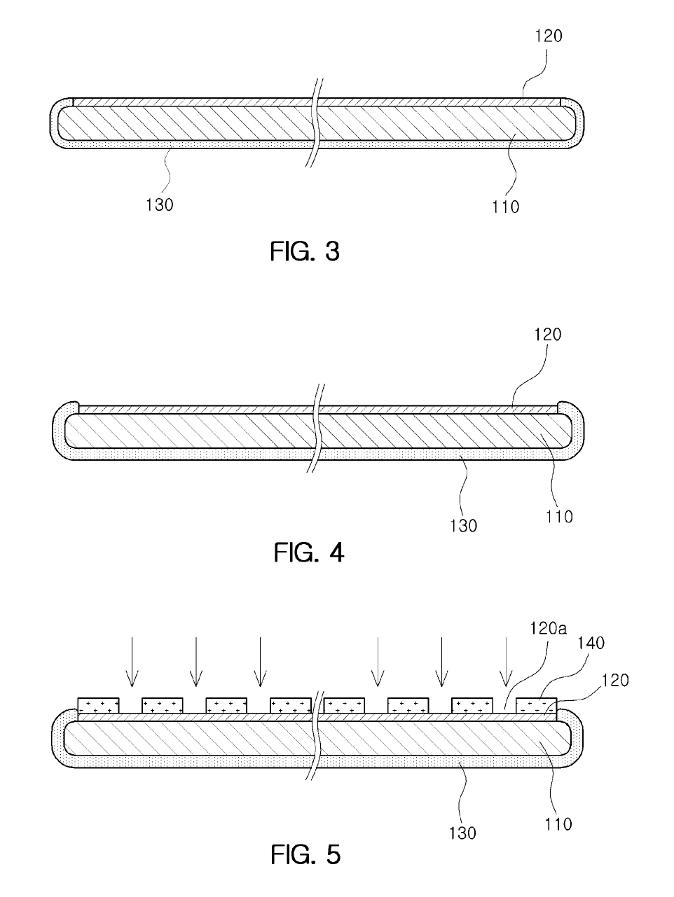

In order to solve such a problem, an oxide film 130 (FIG. 3) maybe grown on the edge portion D, thereby preventing defects from occurring thereon during the manufacturing process.

The protective layer 120 (FIG. 2) may be disposed on the substrate 110 using a material having an etching rate different from that of the oxide film 130, prior to the forming of the oxide film 130 on the edge portion D of the substrate 110.

Therefore, one of the protective layer 120 or the oxide film 130 may be selectively removed according to the selection of an etching solution or an etching gas.

The protective layer 120 may be formed by depositing a nitride film on a surface of the substrate 110, except for the edge portion D of the substrate 110. The protective layer 120, formed on the surface of the substrate 110 except for the edge portion D, may be obtained by forming the nitride film on the surface of the substrate 110. This is achieved by only forming a mask on an area of the surface of the substrate 110 except for the edge portion D, etching an area thereof in which the mask is not formed and removing the same.

Here, the protective layer 120 may be formed of a nitride film selected from the group consisting of SiON, SiNₓ and a mixture thereof. The nitride film may be formed by chemical vapor deposition (CVD) , sputtering, or plasma enhanced chemical vapor deposition (PECVD) .

Next, as shown in FIG. 3, the oxide film 130 may be formed on the entirety of the surface of the substrate 110 except for the protective layer 120.

The oxide film 130 is a fine film formed on the entirety of the surface of the substrate 110 except for where the protective layer 120 is disposed . The oxide film 130 may serve as a seed layer for growing a thick oxide film in a subsequent process.

The oxide film 130 may be deposited by placing the substrate 110 having the protective layer 120 formed thereon in a chamber and supplying O₂ gas to the chamber.

Next, as shown in FIG. 4 and compared with FIG. 3, the oxide film 130 may be grown to be thick. The growth of the oxide film 130 may be performed by a known growth method to which the present application pertains.

Here, the oxide film 130 may be grown to have a thickness of at least 5 μm or greater. In a case in which the oxide film 130 is grown to have a thickness of at least 5 μm or greater, even after the etching process is performed during the manufacturing process, the oxide film 130 may still protect the edge portion D. In this manner, the edge portion D may be prevented from being etched during the etching process.

Thereafter, the protective layer 120 may be selectively etched to thereby form a through hole 111a (FIG. 7) in a thickness direction of the substrate 110.

The selective etching of the protective layer 120 may be performed using a CHₓF_{y} gas. Specifically, in this example, the etching process may be performed using a CH₂F₂ gas or CH₃F gas as the CHₓF_{y} gas.

The CHₓF_{y} gas may have a high etching rate with respect to a nitride film, while it may have a low etching rate with respect to an oxide film.

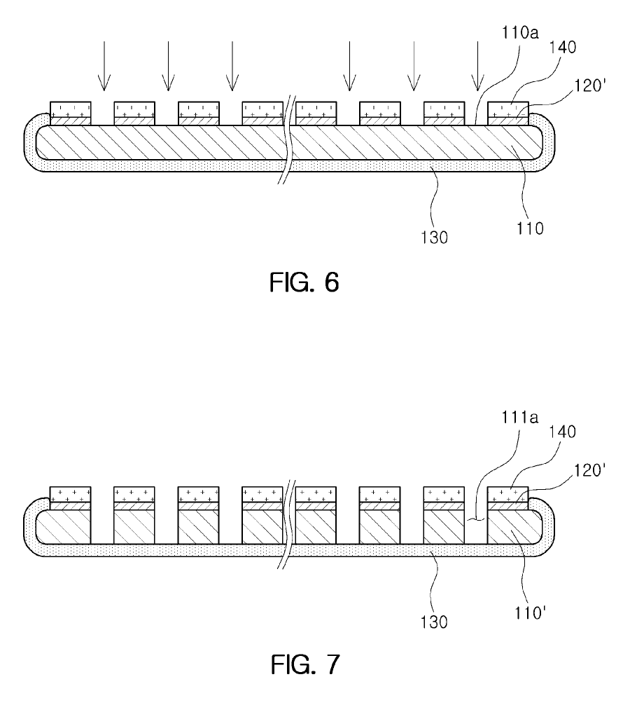

As shown in FIG. 5, a mask 140 is formed on the protective layer 120 and a portion 120a of the protective layer 120 is exposed between patterns of the mask 140 when etched using the CHₓF_{y} gas. The etching process of the oxide film 130 may be suppressed and only the exposed portion 120a of the protective layer may be selectively removed. FIG. 6 is a cross-sectional view illustrating the selective removal of the exposed portion 120a of the protective layer.

Then, a portion 110a of the substrate 110 exposed by selectively etching the protective layer 120 is etched to thereby form the through hole 111a, as shown in FIG. 7.

At least one through hole 111a may be formed in the thickness direction of the substrate 110. The through hole 111a may be formed as a space having a pipe shape passing through the substrate 110 in the thickness direction thereof. The space may have a cylindrical shape, a polygonal shape or the like.

In the present example, the space may be formed to have a cylindrical shape.

In this case, the through hole 111a may be formed by performing dry etching on the exposed portion 110a of the substrate 110. The dry etching is not particularly limited, and a known etching method may be used. Specifically, the through hole 111a may be formed by a laser-drilling method.

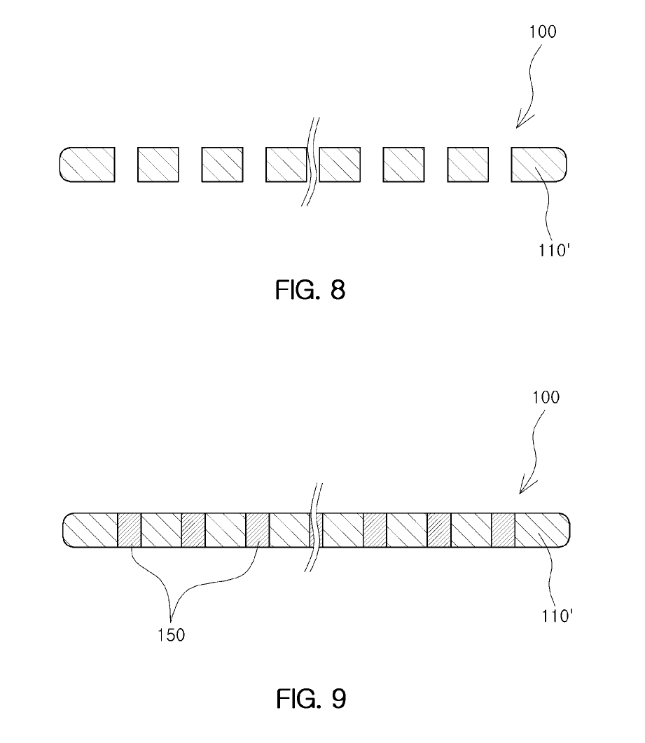

Turning now to FIG. 8, the entirety of the surface of the substrate 110′ may be etched to thereby remove the protective layer 120′, the mask 140 and the oxide film 130 formed on the substrate 110′.

This etching process may be performed by wet etching. Here, an etching solution used in the wet etching process may be any one of KOH, H₂50₄ and H₂PO₄. Since the protective layer 120′, the mask 140 and the oxide film 130 may be easily etched relative to the substrate 110′, the protective layer 120′, the mask 140 and the oxide film 130 may be removed through the etching process and the substrate 110′ may be left.

Next, as shown in FIG. 9, an electrode 150 maybe formed by filling the through hole 111a with metal.

The electrode 150 may be formed by preparing a paste using a conductive material selected from the group consisting of Ni, Au, Ag, Ti, Cr and Cu and filling the through hole 111a therewith. Alternatively, the electrode 150 may be formed by a plating method known in the art or the like.

Since the through hole 111a is formed in the substrate 110 after growing the oxide film 130 on the edge portion D of the substrate 110, defects in the edge portion D during the etching process may be prevented.

As set forth above, in a method of manufacturing a substrate for mounting an electronic device according to the present examples, defects in the substrate during the manufacturing process thereof may be reduced, whereby manufacturing costs thereof can be reduced.

While the foregoing has described what are considered to be the best mode and/or other examples, it is understood that various modifications may be made therein and that the subject matter disclosed herein may be implemented in various forms and examples, and that the teachings may be applied in numerous applications, only some of which have been described herein.

It is intended by the following claims to claim any and all applications, modifications and variations that fall within the true scope of the present teachings.

What is claimed is:

1. A method of manufacturing a substrate for mounting an electronic device, the method comprising steps of:
disposing a protective layer on a surface of the substrate except for an edge portion thereof;
disposing an oxide film on the entirety of the surface of the substrate except for where the protective layer is disposed;
growing the oxide film;
forming at least one through hole in a thickness direction of the substrate by selectively etching the protective layer; and
removing the oxide film.

2. The method of claim 1, wherein the substrate is a Si substrate.

3. The method of claim 1, wherein the edge portion has a width of 30 μm in a direction from an edge of the substrate toward a center thereof.

4. The method of claim 1, wherein the protective layer is formed by depositing a nitride film on the substrate.

5. The method of claim 4, wherein the nitride film is selected from the group consisting of SiON, SiNₓ and a mixture thereof.

6. The method of claim 1, wherein the oxide film is deposited by supplying O₂ gas to the substrate.

7. The method of claim 1, wherein the oxide film is grown to have a thickness of 5 μm or greater.

8. The method of claim 1, wherein the step of forming the through hole includes:
forming a mask having patterns on the protective layer,
selectively etching the protective layer exposed between the patterns to allow a portion of the substrate to be exposed, and
etching the exposed portion of the substrate to form the through hole.

9. The method of claim 8, wherein the selective etching of the protective layer is performed using a CHₓF_{y} gas.

10. The method of claim 9, wherein the CHₓF_{y} gas is a CH₂F₂ gas or CH₃F gas.

11. The method of claim 1, wherein the protective layer and the oxide film have different etching rates.

12. The method of claim 1, the method further comprising the step of:
forming an electrode by filling the through hole with a metal.

13. A method of manufacturing a substrate comprising steps of:
disposing a protective layer on a first surface of the substrate;
disposing an oxide seed layer on a second surface of the substrate, wherein the first and second surfaces do not overlap and the oxide seed layer is disposed over one or more edges of the substrate;
growing the oxide seed layer to form an oxide film, the oxide film having a thickness greater than the oxide seed layer;
forming a plurality of through holes in a thickness direction of the substrate by selectively etching the protective layer; and
removing the oxide film.

14. The method of claim 13, wherein the substrate is a Si substrate.

15. The method of claim 13, wherein the protective layer is formed by depositing a nitride film on the first surface of the substrate

16. The method of claim 15, wherein the nitride film is selected from the group consisting of SiON, SiNₓ and a mixture thereof.

17. The method of claim 13, wherein the oxide seed layer is deposited by supplying O₂ gas to the substrate.

18. The method of claim 17, wherein the oxide seed layer is grown to form the oxide layer having a thickness of 5 pm or greater.

19. The method of claim 13, wherein the step of forming the plurality of through holes includes:
forming a mask having patterns on the protective layer,
selectively etching the protective layer exposed between the patterns to allow a portion of the substrate to be exposed, and
etching the exposed portions of the substrate to form the plurality of through holes.

20. The method of claim 19, wherein the selective etching of the protective layer is performed using a CHₓF_{y} gas.
